(19) United States
(12) Patent Application Publication
(10) Pub. No.: US 2002/0172767 A1
(43) Pub. Date: Nov. 21, 2002

(54) Chemical vapor deposition growth of single-wall carbon nanotubes

(76) Inventors: Leonid Grigorian, Arvada, CO (US); Louis Hornyak, Evergreen, CO (US); Anne Dillon, Boulder, CO (US); Michael J. Heben, Denver, CO (US)

Correspondence Address: MORGAN LEWIS & BOCKIUS LLP, 1111 PENNSYLVANIA AVENUE NW, WASHINGTON, DC, 20004, US

(21) Appl. No.: 09/825,870

(22) Filed: Apr. 5, 2001

(51) Int. Cl. D01F 9/12; C23C 16/00

(52) U.S. Cl. 427/255.28; 423/447.3

(57) ABSTRACT

The invention relates to a chemical vapor deposition (“CVD”) process for the growth of single-wall carbon nanotube (“SWNT”). According to the invention, methane gas is decomposed in the presence of a supported iron-containing catalyst to grow SWNT material within a growth temperature range from about 670° C. to about 800° C. The process provides higher yields of SWNT material and reduces the formation of amorphous carbon. Thus, the SWNT material produced according to the invention will minimize problems associated with purification steps, such as breakage or damage to the SWNT material. The invention provides for the manufacture of SWNT material at lower temperatures, which not only results in lower equipment and processing costs, but also provides compatibility with substrates that cannot be used at higher temperatures. The invention may be used to provide an inexpensive process for the mass production of SWNT material.

### CONTRACTUAL ORIGIN OF THE INVENTION

The United States Government has rights in this invention under Contract No. DE-AC36-99GO10337 between the United States Department of Energy and the National Renewable Energy Laboratory, a Division of the Midwest Research Institute.

### FIELD OF INVENTION

The invention relates to a chemical vapor deposition (“CVD”) process for the growth of single-wall carbon nanotube (“SWNT”). More particularly, the invention relates to a process where methane gas is decomposed in the presence of a supported iron-containing catalyst to grow SWNT material within a growth temperature range from about 670° C. to about 80⁰° C.

### BACKGROUND

Fullerenes were discovered in 1985 by Curl, Kroto, and Smalley, and carbon nanotubes were discovered a few years later by Sumio lijima in 1991. See Kroto, H. W., Heath, J. R., O'Brien, S. C., Curl, R. F. and Smalley, R. E. “C₆₀: Buckminsterfullerene”, Nature, 318, 162-163 (1985) and lijima, “Helical Microtubules of Graphitic Carbon”, Nature, 354(7), 56-58 (1991). Since these discoveries, much research has been devoted to learning more about the physical and chemical properties of carbon nanotube materials, as well as potential applications for these materials. However, research has been limited by the lack of a practical method for producing high quality carbon nanotube material on a large scale and at a reasonable cost.

The most common methods specifically for the preparation of single wall carbon nanotube (“SWNT”) material include laser evaporation, electric arc discharge, and chemical vapor deposition methods. However, each of the techniques developed to date has various shortcomings for the large-scale production of high purity SWNT material.

Laser evaporation of graphite has been used to produce SWNT material. In such a process, a laser is used to vaporize a heated carbon target that has been treated with a catalyst metal. In Guo, T. et al, Chem. Physics Letters, 243, 49 (1995), and Bandow, S. et al., Physical Review Letters, 80(17), 3779-3782 (1998), a graphite rod having cobalt or nickel dispersed throughout is placed in a quartz tube filled with about 500 Torr of argon, followed by heating to 1200° C. An laser is then focused on the upstream side of the quartz tube from the tip to heat the carbon rod and evaporate it. Carbon nanotubes are then collected on the downstream side of the quartz tube. Laser ablation of a heated target is reported in Thess, A. et al., Science, 273, 483-487 (1996), where a laser is used to vaporize a heated carbon target that has been treated with a catalyst metal such as nickel, cobalt, iron, or mixtures thereof.

An electric arc discharge method for preparation of SWNT has been reported in lijima, Nature, 354(7), 56-58 (1991) or Wang et al., Fullerene Sci. Technol., 4, 1027 (1996), for example. In this method, carbon graphite is vaporized by direct-current electric arc discharge, carried out using two graphite electrodes in an argon atmosphere at approximately 100 Torr. SWNT are grown on the surface of the cathode.

Chemical vapor deposition approaches for growing SWNT material typically use methane, carbon monoxide, ethylene or other hydrocarbons at high temperatures with a catalyst. Chemical vapor deposition of an aerogel supported Fe/Mo catalyst at 850-1000° C. is reported, for example, in J. Kong, A. M. Cassell, and H. Dai, Chemical Physics Letters, 292, 567-574 (1998) and Su, M., Zheng, B., Liu, J., Chemical Physics Letters, 322, 321-326 (2000). The chemical vapor deposition of methane over well-dispersed metal particles supported on MgO at 1000° C. is reported in Colomer, J. -F., et al., Chemical Physics Letters, 317, 83-89 (2000). In Japanese Patent No. 3007983, a CVD process for production of carbon nanotubes is reported where a hydrocarbon is decomposed at 800-1200° C. in a reactor containing a catalyst comprising molybdenum or a metal molybdenum-containing material. In addition to the above methods, a carbon fiber gaseous phase growth method has been reported in WO 89/07163, where ethylene and propane, with hyperfine metal particles are inducted to produce SWNT at 550-850° C.

WO 00/17102 discloses that SWNT material can be prepared by catalytic decomposition of a carbon-containing compound, (e.g., carbon monoxide and ethylene), over a supported metal catalyst at initial temperatures of about 700° C. to about 1200° C., preferably an initial temperature of 850° C. WO 00/17102 asserts that “the mass yield of SWNT is temperature dependent, with the yield increasing with increasing temperature” at page 13, lines 18-19.

EP 1,061,041 teaches a low-temperature thermal chemical vapor deposition apparatus and method of synthesizing carbon nanotubes using the apparatus. This apparatus has a first region, maintained at a temperature of 700° C. to 1000° C., and a second region maintained at 450-650° C. In this process, a metal catalyst is used with a hydrocarbon gas having 1-20 carbon atoms as the carbon source, preferably acetylene or ethylene.

All of the methods developed to date, however, have various shortcomings. Such methods for preparing carbon nanotubes are not only expensive, but also fail to provide carbon nanotubes in high yields or in a cost effective manner. Moreover, the material produced by the current methods in the art often produce a material of low purity and/or low quality. In current prior processes, SWNT is typically produced by high temperature processes, often with concomitant formation of significant amounts of amorphous carbon, which typically results in low yields and requires extensive purification steps. The purification techniques themselves often contribute to the low yields by causing damage or breakage of the carbon nanotubes. As a result, the current processes for making SWNT material are expensive and generally prohibit large scale production of SWNT material.

Thus, what is needed in the art is a process for the production of SWNT that is less expensive, high-yielding, and preferably suitable for mass production of SWNT material. Such a process should preferably produce high quality SWNT material with minimal amounts of side products such as amorphous carbon. As an additional benefit, the process should produce carbon nanotubes of high purity, thereby minimizing problems of breakage or damage to SWNT material, commonly associated with extensive purification of the SWNT material. This invention answers that need.

### SUMMARY

The invention relates to a chemical vapor deposition (“CVD”) process for the preparation of a SWNT from methane within a growth temperature (T_{g}) range of about 670° C. to about 800° C. By growing SWNT material within this growth temperature range, it is possible to achieve not only higher yields of SWNT, but also minimize production of amorphous carbon and other side products, as compared to other CVD processes for growing SWNT material at higher temperatures. Outside this temperature range, the SWNT yield drops dramatically even though the overall mass gain may increase due to amorphous carbon deposition. In addition, the invention has the advantage of being run at lower temperatures, which has the benefit of lower operating costs, lower equipment costs, and compatibility with substrates which cannot be used at higher temperatures. The invention may be used in a relatively inexpensive process for the mass production of SWNT material.

According to the invention, SWNT material is grown under chemical vapor deposition conditions using a methane gas within a growth temperature (T_{g}) range from about 670° C. to about 800° C. Methane gas is fed into a CVD chamber that contains a supported iron-containing catalyst. The methane gas may optionally be introduced with a carrier gas, such as argon, nitrogen, helium, or mixtures thereof. In the CVD chamber, the methane gas is decomposed in the presence of the catalyst within a growth temperature (T_{g}) range from about 670° C. to about 800° C., under a sufficient gas pressure and for a time sufficient to produce SWNT material. In an embodiment of the invention, the growth of the SWNT material is typically carried out for less than about four hours, preferably for less than about one hour, and most preferably for about 30 minutes to about 60 minutes. After the SWNT material is grown, the methane gas is replaced with an inert gas, such as argon, and the CVD chamber is cooled, i.e. to about room temperature. The SWNT material may then be collected, purified, and/or characterized for various applications.

Any of the embodiments of the invention may be used either alone or taken in various combinations to provide SWNT material according to the invention. Additional objects and advantages of the invention are discussed in the detailed description that follows, and will be obvious from that description, or may be learned by practice of the invention. It is to be understood that both this summary and the following detailed description are exemplary and explanatory only and are not intended to restrict the invention.

### BRIEF DESCRIPTION OF THE FIGURES

FIG. 1 is a TEM image of CVD-grown SWNT material, which was grown at 1000° C.

FIG. 2 is a TEM image of CVD-grown SWNT material, which was grown at 700° C.

FIG. 3 shown the tangential modes in a Raman spectra of SWNT material.

FIG. 4 shown the radial breathing modes in a Raman spectra of SWNT material.

FIG. 5 shows the evolution of Raman spectra as T_{g} is increased from 670° C. to about 1000° C.

FIG. 6 shows the mass gain due to carbon deposition, as a function of T_{g}.

FIG. 7 shows the variation of the Raman intensity of SWNT, as a function of T_{g}.

### DETAILED DESCRIPTION

The invention relates to a chemical vapor deposition (CVD) process for the preparation of a single-wall carbon nanotube (SWNT) from methane, using a supported iron-containing catalyst and carried out within a growth temperature (T_{g}) range from about 670° C. to about 800° C. By growing SWNT material within this temperature range, it is possible to not only achieve higher yields of SWNT, but also reduce the amount of amorphous carbon and minimize other side products, compared to other CVD processes for growing SWNT material.

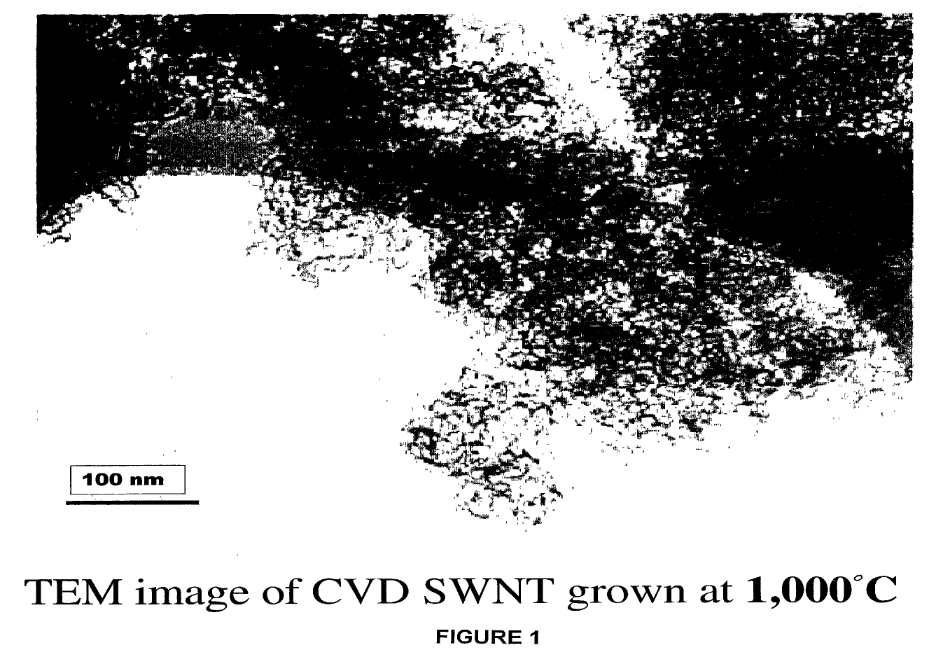

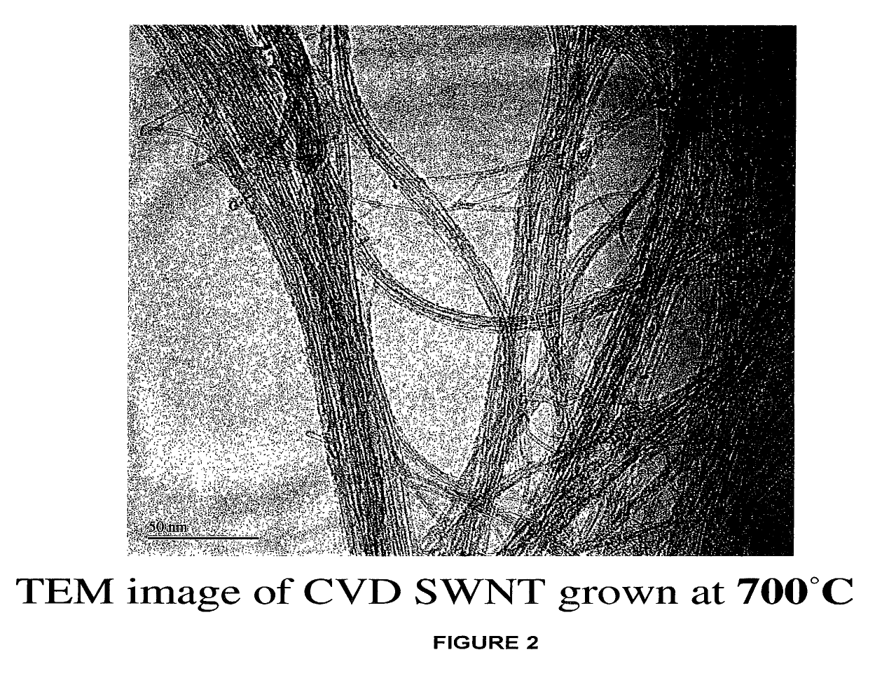

FIG. 1 is a TEM image of CVD-grown SWNT material, which was grown at 1000° C. FIG. 2 is a TEM image of CVD-grown SWNT material, which was grown at 700° C. The image in FIG. 2 shows abundant SWNT throughout the sample prepared at 700° C., while in the image in FIG. 1 shows that the sample prepared at 1000° C. contained only a few SWNT in some of the regions.

According to a first step of the invention, methane gas is introduced into a chemical vapor deposition chamber containing a supported iron-containing catalyst. Next, the methane gas is decomposed in the presence of the supported iron-containing catalyst, under a sufficient gas pressure and for a time sufficient, to grow single-wall carbon nanotubes within a temperature range from about 670° C. to about 800° C. The SWNT material may then be collected, purified, and characterized. SWNT material may be used in a variety of applications, including but not limited to hydrogen storage devices, electronic applications, biological and medical applications and various chemical applications.

### Growth Temperature Window

Initially an inert gas, such as argon, flows through the quartz tube while the chemical vapor deposition chamber is heated to the desired temperature range, i.e. about 670° C. to about 800° C. Once the desired temperature is achieved, the inert gas is replaced with methane at a sufficient flow rate and pressure to grow SWNTs.

In other embodiments of the invention, the SWNTs are grown within a temperature range from about 670° C. to about 750° C., or about 670° C. to about 700° C. The growth temperature (t_{g}) range used in the invention is specific for methane. As discussed later, the choice of catalyst and flow rate also affect the growth temperature to be used. In general, the lowest possible temperature should be used, in order to minimize formation of amorphous carbon, while obtaining the optimal amount of SWNT material.

### Methane Gas and Carrier Gasses

To form SWNT material according to the invention, methane gas is introduced into the chemical vapor deposition chamber. Commercially available methane gas is typically used. It is preferable to use high grade methane gas, for example, 99% purity or higher.

The methane gas may optionally be introduced with an inert carrier gas. Typical inert carrier gases include argon, nitrogen, helium, neon, and mixtures thereof. The carrier gas may be used in an amount that is suitable for chemical vapor deposition. Typically, the carrier gas will be used in a ratio of methane to carrier gas of about 1:1 to 1:10.

The methane gas or methane gas mixture is introduced at a sufficient pressure for the growth of the SWNT. Preferred gas pressures are from about 400 to about 600 Torr. For example, typical CVD processes are preferably run at a total gas pressure of about 600 Torr.

The gas flow rate should preferably be from about 200 to about 500 sccm for the carrier gas and from about 20 to about 60 sccm for the methane. As an example, typical CVD processes are preferably run at a flow rate of about 400 sccm for argon and 40 sccm for methane.

### Catalysts, Catalyst Supports, and Substrates

According to the invention the nanotubes may be grown using a supported iron-containing catalyst. In a preferred embodiment, the catalyst is a supported catalyst, containing iron or mixtures of iron with Co and/or Mo. Examples of supported iron-containing catalysts include Al₂O₃/Fe/Mo/Co, Al₂O₃/Fe/Mo, Al₂O₃/Fe/Co, Al₂O₃/Fe, and mixtures thereof. Catalysts such as Al₂O₃/Fe/Mo are particularly preferred.

The catalyst will preferably be a supported catalyst, which may be prepared by any suitable method known in the art. For instance, the catalyst may be prepared by impregnating the support material with a solution of the catalyst material or catalyst precursors. In a preferred embodiment, the support material used is Degussa fumed-alumina, 100m²/g surface area. In a typical procedure, a mixture of the precursors and support are combined with a solvent, such as water or a suitable alcohol (e.g. methanol, ethanol, isopropanol, and mixtures thereof), and stirred for a sufficient amount of time to impregnate the support, i.e. about an hour at room temperature, depending on the catalyst. The solvent may then be removed using means known in the art, e.g. a rotary evaporator, with heating if necessary. The resulting solid material is then heated overnight at a sufficient temperature to further remove traces of the solvent, i.e. 150° C., depending on the catalyst. Next, the solid material is ground into a fine powder.

Complex catalyst supports based on Al₂O₃ and SiO₂ are typically made by first suspending SiO₂ in HF solution, and then mixing with Al₂O₃. See J. Kong, A. M. Cassell, and H. Dai, Chemical Physics Letters, 292, 567-574 (1998). However, it has been found that in certain circumstances, the HF may react with other metals and/or participate in unwanted side reactions. In such situations, it is preferred to use Al₂O₃ only. In particular, it has been found that γ-phase fumed Al₂O₃, having a surface area of 100 m²/gram, commercially available from Degussa, Ridgefield Park, N.J., is preferred.

Preferred alumina-supported Fe:Mo bimetallic catalyst have a molar ratio of Al₂O₃:Fe:Mo of about (10-20): 1:⅓. This catalyst can be prepared by an aqueous incipient wetness method, as known in the art. For example, in a typical procedure, alumina-supported Fe:Mo catalyst was formed by stirring Fe₂(SO₄)₃·5H₂O, (NH₄)Mo₇O₂₄·4H₂O and Degussa alumina in deionized water for about 1 hour, followed by ultrasonication for about 3 hours and drying in an oven at about 100° C. overnight. The dried material was then ground and calcined under argon flow at about 950° C. for approximately 10 minutes.

### Chemical Vapor Deposition

The chemical vapor deposition process used in the invention involves heating methane gas, and delivering the heated methane gas to the surface of a heated substrate. In a preferred embodiment, the methane gas typically heats up while traveling through the furnace, without requiring a pre-heating step. CVD is well known in the art, and described in detail in handbooks such as Pierson, H. O., Handbook of CVD Principles: Techniques and Applications, William Anderson LLP, New York, N.Y. (1999). According to the CVD process of the invention, the heated methane gas is condensed in the presence of a catalyst or substrate having a supported iron-containing catalyst to form the SWNT material, within a growth temperature of about 670° C. to about 800° C.

In a preferred embodiment, the catalyst is placed in a quartz tube mounted in a tube furnace. The amount of catalyst can be determined by one of ordinary skill in the art, but typically about 10 mg to about 100 mg of catalyst is used. The chemical vapor deposition chamber may be any suitable CVD-apparatus known in the art. For example, a tube furnace may be used. The tube furnace is particularly well suited for growth of SWNTs, because the temperature can be controlled with precision. This type of furnace holds a tube, which is surrounded by heating elements for heating the tube to a desired temperature.

Samples are usually either placed directly in the tube furnace, or placed on “boats”, which are essentially trays for carrying the samples. Boats are preferably made of quartz or ceramic materials.

### Growth Time for SWNT

The methane gas is decomposed for a time sufficient to grow the SWNT material. In one embodiment, the SWNT material is typically grown for a time of less than about four hours, more preferably less than about one hour. In a most preferred embodiment, the SWNT is grown for about 30 minutes to about 60 minutes. The growth time should be controlled to maximize SWNT growth, while minimizing the deposition of amorphous carbon.

After the SWNT growth is complete, the methane gas is replaced with argon and the furnace is cooled to room temperature. The growth under the described conditions is typically complete in about one hour.

### Collection and Purification of SWNT Material

After the SWNT material is grown, the SWNT material is collected, and it may be desirable to optionally purify the material. For a general discussion of purification of SWNT material, see A. Dillon, “A Simple and Complete Purification of Single-Walled Carbon Nanotube Materials”, Adv. Mater., 11(16) (1999). For example, the final products may be treated with an aqueous solution (e.g. typically in concentrations from about 1-5M) of an inorganic acid, such as a mineral acid to remove any excess catalyst particles. Suitable mineral acids include, for example, sulfuric acid, nitric acid, and hydrochloric acid.

Other suitable methods for purifying SWNT material known in the art may also be used. Examples of such methods include the use of oxidants, burning, and surfactants. Care should be taken with such methods to minimize unwanted side reactions such as breaking of chemical bonds of the SWNT and poor yields.

### Analysis and Characterization of SWNT Material

A single wall carbon nanotube (“SWNT”) is a molecule formed primarily from Sp²-hybridized carbon atoms bound together in the shape of a hollow tube that is capped at each end. Typically, for example, the carbon nanotubes will be made of tubes of graphite sheet capped with half a fullerene molecule on each end. Carbon nanotubes are further classified as either single wall carbon nanotubes (“SWNT”) or multiple wall carbon nanotubes (“MWNT”). SWNT are one atomic carbon layer in thickness and MWNT are more than one atomic carbon layer in thickness. Typically, a SWNT has a diameter of less than about 3 nm, while a MWNT has a diameter of greater than about 2.5 nm.

The SWNT material that is produced according to the invention may be characterized by a variety of methods known to one of ordinary skill in the art. For example, SWNT material is typically characterized by techniques such as Raman spectroscopy. The Raman technique for analysis of SWNTs is described, for example, in Dillon et al, “A Simple and Complete Purification of Single-Walled Carbon Nanotube Materials”, Adv. Mater. 11(16), 1354-1358 (1999). Purified SWNT material shows two strong Raman signals (tangential modes) at about 1593 and 1567 cm⁻¹. These signals will increase in intensity as the material is purified and the percent of SWNT material increases. (A slight blue shift to the signal, as the material is purified has been reported. The basis for this shift is not completely understood.) A signal at 1349 cm⁻¹ (“D-band”) in the crude material is tentatively assigned to the presence of impurities and defects in the nanotube walls.

Purified, 100% SWNT sample exhibits extremely strong tangential modes and very weak D-bands. The intensity ratio of these two bands increases with the increasing SWNT fraction relative to other forms of carbon and is close to 100 for the 100% SWNT sample. From the value of the ratio of the tangential-to-D bands (about 30 in the best samples), it is estimated that the SWNT fraction comprises about 30 wt % of the carbon deposit in samples grown inside the T_{g} window. The low-temperature approach to the “window” T_{g} values (defined as the range of T_{g} over which the Raman intensity due to SWNT grows to its maximum) is much sharper (about 10° C) than the high-temperature boundary, possibly due to thermodynamics, i.e. SWNT start growing at certain critical temperature where the free energy for SWNT becomes negative.

As demonstrated by the invention, efficient SWNT growth occurs only within a “window” of growth temperatures, T_{g}.While not wishing to be bound by theory, it is thought that the lower T_{g} boundary of this “window” is apparently determined by thermodynamics. In other words, SWNT starts growing when its free energy becomes negative at high enough T_{g},thereby making this process energetically favorable. On the other hand, the higher temperature boundary (which is less sharp, as compared to the low temperature one) seems to be correlated with the onset of pyrolysis (thermal decomposition without the aid of the catalyst) of the methane. It is believed that the competition between the pyrolysis and the ordered SWNT growth on the catalyst sites is heavily in favor of the pyrolysis, due to much larger surface area available for pyrolysis as compared to the catalyst-covered area promoting the SWNT growth. For the particular experimental conditions set forth above, i.e. using methane as the carbon source and using a supported iron-containing catalyst, the growth temperature “window” is about 670° C. to about 800° C.

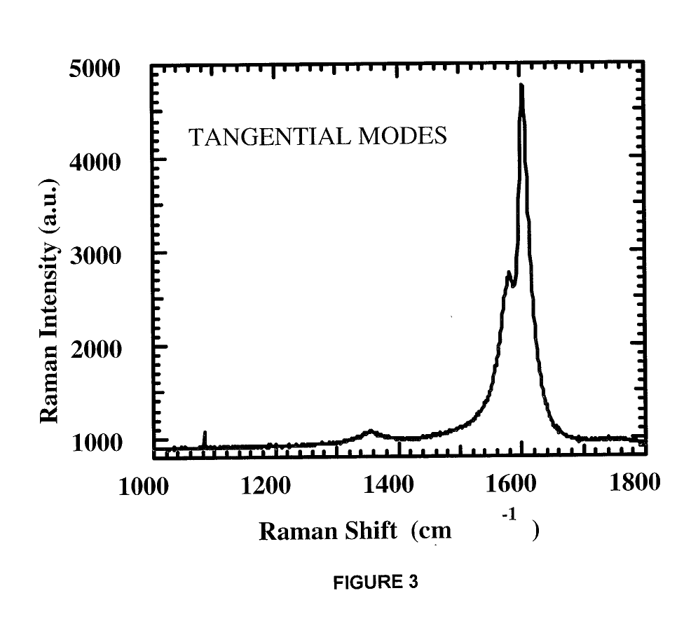

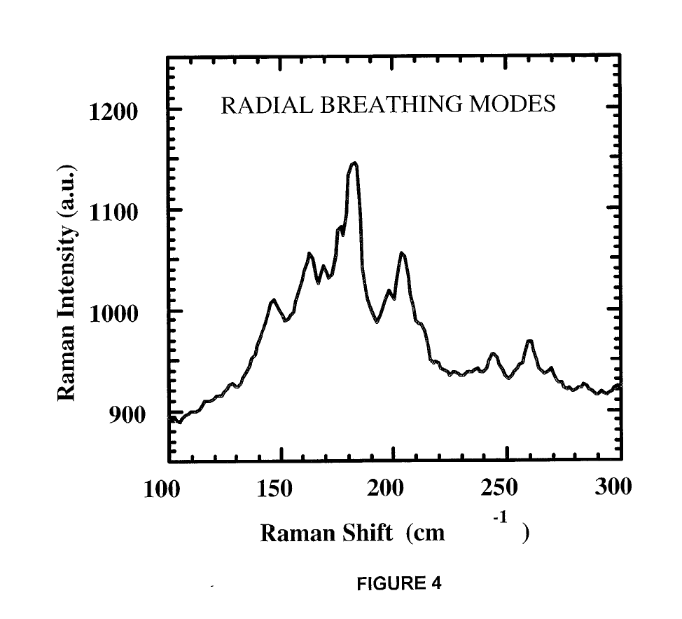

FIG. 3 and FIG. 4 show typical Raman spectra of SWNT grown by the CVD process of the invention. FIG. 3 shows the “tangential” Raman modes, and the high intensity of these modes indicates a high content of SWNT in the sample comparable with the best laser-grown samples.

FIG. 4 shows the radial “breathing” modes that provide information on the diameter distribution of individual SWNTs in the sample. In particular, each peak corresponds to one diameter (the frequency) of the radial mode and is inversely proportional to the SWNT diameter. The CVD-grown samples typically exhibit very broad diameter distribution ranging from about 0.7 nm to about 2.1 nm. In contrast, the laser-grown or arc-grown SWNT diameters range from about 1.2 to about 1.6 nm, corresponding to radial modes between about 150 cm⁻¹ and 200 cm⁻¹.

The diameter of a SWNT (“d” in nm) can be calculated according to the following formula:

d(nm)=223.75/ωᵣ(cm¹)

In this formula, ωᵣ is the radial breathing mode frequency. See also Bandow, S. et al, “Effect of the Growth Temperature on the Diameter Distribution and Chirality of Single-Wall Carbon Nanotubes”, Physical review Letters, 80(17), 3779-3782 (1998), which is hereby incorporated by reference in its entirety. According to this reference, Raman spectra were obtained for nanotube material; the spectra were unpolarized and were collected in the backscaftering configuration, using about 488-1064 nm excitation on the samples. Raman scattering from vibrational modes are related to the diameter for all SWNT symmetry types, including chiral, zigzag, and armchair. In other words, ωᵣ is reported to be sensitive only to inverse diameter and is not sensitive to the helicity or symmetry of the SWNT.

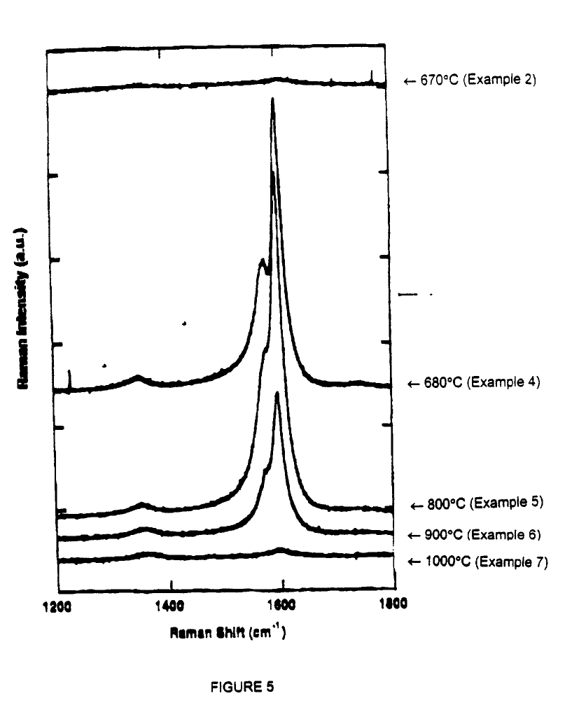

FIG. 5 shows the evolution of Raman spectra as T_{g} is increased from 670° C. to about 1000° C. (See Examples 2 and 4-7.) There was no notable amount of carbon deposit (and no detectable Raman bands) at T_{g}<670° C. The Raman spectra were essentially similar for the carbon deposits produced at T_{g} between 650° C. and 670° C., indicating the presence of only amorphous carbon. At T_{g} around 672° C., new strong Raman bands appear at around 1593 (with a shoulder at 1870) and 1350 cm⁻¹ which are assigned to only SWNT material. The intensity of the Raman bands due to SWNT increases sharply over a very narrow T_{g} range, and reaches a plateau spreading from T_{g} about 700° C. to about 800° C. With further increase in T_{g} over 800° C., the Raman intensity starts to drop, and the bands due to SWNT almost disappear at T_{g} about 1000° C.

This data indicates that under conditions according to the invention, SWNT can grow efficiently within a narrow T_{g} range, while outside of this window, there is either no carbon deposit at all, or it is predominantly amorphous carbon. This conclusion has been supported by TEM images taken from the samples deposited at 700° C. and 1000° C., as shown in FIG. 1 and FIG. 2.

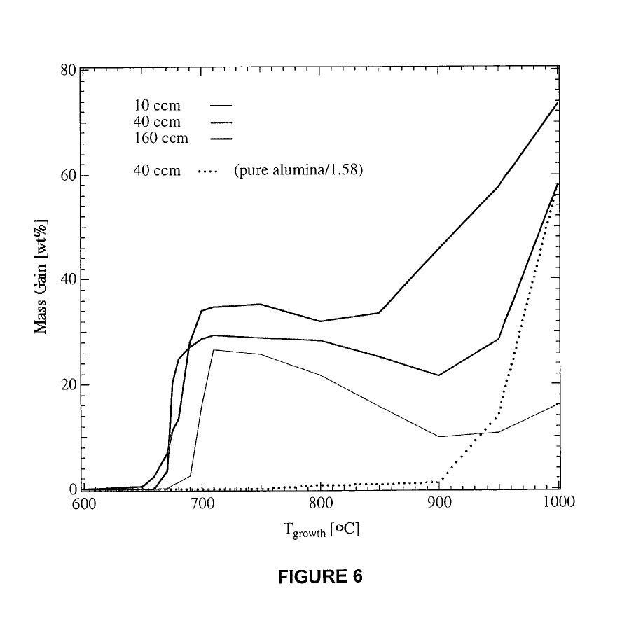

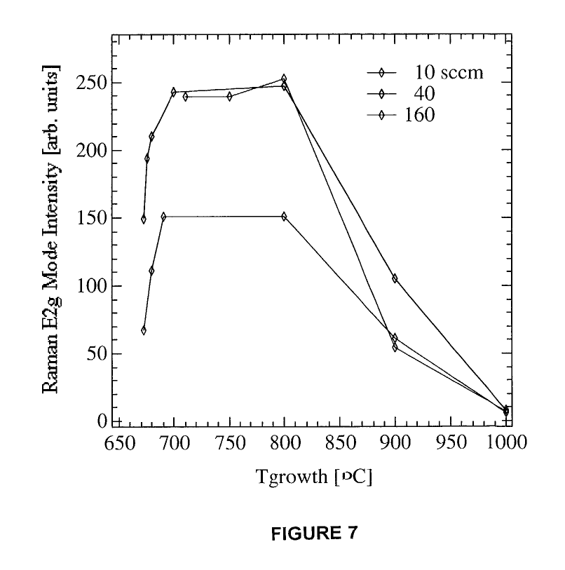

FIG. 6 shows the mass gain due to carbon deposition, as a function of T_{g}, and FIG. 7 shows the variation of the Raman intensity due to SWNT also as a function of T_{g}. The CVD-grown carbon samples were characterized by a combination of mass gain (yield of carbanaceous material) and Raman spectra (λ=488 nm). The Raman data is used to estimate what fraction of the overall carbon grown in the CVD experiment is SWNT material, as the SWNT signal is resonantly enhanced in Raman, making this technique extremely sensitive to the SWNT.

In FIG. 6, the curves closely trace each other at the low temperature side (T_{g}<700° C.) of the window, but they diverge at the high temperature side (T_{g}>800° C.) and the divergence is increasing with the increasing T_{g}. In FIG. 7, the Raman spectra track the presence of SWNT material. These results in FIG. 6 and FIG. 7 show that the carbon deposit produced at T_{g}>800° C. consists mainly of amorphous carbon even though the mass gain is increased.

### Applications for SWNT

The SWNT material produced by the invention may be used for a variety of applications. For example, due to the very high uptake of hydrogen in the SWNT material, SWNT might be used for the storage of hydrogen in fuel-cell electric vehicles. See Dillon, A. C., et al., Nature, 386, 377-379 (1997). There has been much pressure to develop alternate fuel sources, mainly due to depletion of petroleum reserves and environmental regulations to develop cleaner burning fuels. Of the many approaches studied to replace the gasoline powered internal combustion engine, (i.e. liquid hydrogen systems, compressed hydrogen systems, metal hydride systems, and superactivated carbon systems), all have shortcomings such as expense, storage and safety issues which have prevented the development to date of a practical storage system for hydrogen. While not wanting to be restricted by theory, it is believed that large quantities of gas can be absorbed inside the pores of the nanotube. Adsorbed hydrogen can be more densely packed using carbon nanotubes than is possible by compressing hydrogen gas.

In other applications, carbon nanotubes can also function as metals, conductors, semiconductors, superconductors, and thus may be useful as transistor and resistor devices for electronic and computer industries. It is also believed that doping the nanotubes will lead to modified electrical properties by substituting the carbon atoms by other atoms, e.g. B, N, of with some defects, thus creating a p-n junction within the sheet.

SWNTs, which have a diameter as small as a nanometer and unidirectional shape, could also be used as a STM/AFM tip for surface testing and analyzing, storage media for H₂ gas and matrix for field emission display. Carbon nanotubes can also be used as molecular pumps, or drug release devices.

The SWNT prepared according to the invention may have any diameter or geometry (i.e. armchair, zigzag, or chiral). The SWNT material may also be any diameter or length. Moreover, the invention also includes SWNTs that may contain additional materials. As an example, for certain applications, the SWNT may be doped, e.g. with boron, phosphorous, oxygen, iodine, etc.

These are only some examples of the potential applications of SWNT material. Other uses have been proposed and some of these are described generally, for example in M. S. Dresselhaus, G. Dresselhaus, and P. C. Eklund, Science of Fullerenes and Carbon Nanotubes, Academic Press, San Diego, Calif., 1996, which is hereby incorporated by reference.

### EXAMPLES

The practice of the invention is disclosed in the following examples, which should not be construed to limit the invention in any way. All materials used are commercially available unless otherwise noted.

The Al₂O₃ used in the experiments is γ-δ phase fumed Al₂O₃, having a surface area of 100 m²/gram, and is commercially available from Degussa, Ridgefield Park, N.J. The Fe₂(SO₄)₃·5H₂O (about 97% pure), (NH₄)Mo₇O₂₄·4H₂O (about 99.98% pure), and CoSO₄·H₂O (about 99.999% pure) are reagent grade and commercially available, for example, from Aldrich Chemical Company, Milwaukee, Wis. The methane (UHP grade, 99.99% pure) and argon (UHP Grade, 99.995% pure) were purchased from Specialty Product and Equipment Airgas Company and Air Liquids Company, respectively. All of the following experiments were carried out using a tube furnace.

### Preparation of the Catalyst

Control Experiment to Determine Amount of Physiabsorbed Water on Al₂O₃:

An Al₂O₃ (1 mg) sample was placed on a platinum pen of a thermal gravimetric analysis (TGA) chamber. The sample was heated in argon at a rate of 5° C. per minute. After about 5 minutes at 800° C., the sample was found to exhibit a very small weight loss (≦2 wt %).

This weight loss may be attributed to the physiabsorbed water as the support material has relatively high surface area (≈100 m²/g) and can therefore be expected to absorb humidity from the air.

Control Experiment to Determine Amount of Amorphous Carbon Deposited on Al₂O₃ Support Under CVD Conditions at 800° C.:

This experiment was carried out in order to determine the weight gain due to amorphous carbon formed due to the thermal pyrolysis of methane at 800° C., under standard CVD reaction conditions.

A sample of Al₂O₃ (50 mg) was heated to 800° C. under an argon atmosphere, without a catalyst present. Next, the Al₂O₃ was exposed to 10% methane in argon, with flow rate of about 240 sccm, at a pressure of about 600 Torr for about one hour. The Al₂O₃ became black due to the layer of amorphous carbon deposited on its surface. However, the weight gain was only about 1-2 wt %, indicating that there will only be a very small amount of amorphous carbon in CVD-grown SWNT at 800° C.

Preparation of Catalyst A (“Fe:Mo”)

Catalyst A was a supported catalyst having Fe:Mo in approximately a 6:1 molar ratio. Catalyst A was prepared by suspending 2,401.4 mg of Al₂O₃ in 170 mL of de-ionized water at 80° C. for 1 hour. Then 513.4 mg of Fe₂(SO₄)₃·5H₂O was added, and the mixture was stirred for 15 minutes. Next, 60.05 mg of (NH₄)Mo₇O₂₄·4H₂O was added and the mixture was stirred for about one hour. The stir bar was removed, and the solution was left in the oven at about 80-90° C., under a stream of nitrogen to dry overnight for 17 hours to form a powder.

The resulting powder is typically homogeneous. However, if that is not the case, then it must be ground up, re-suspended in water, and dried again. In this particular example, the resultant powder was not homogeneous, i.e. yellow flakes and a white collar ring were observed in the product after drying, indicating inhomogenous mixing of the ingredients. Therefore, the residue was ground, and dissolved in 170 mL of de-ionized water. The solution was sonicated at 50-60° C. for about 2.5-3.0 hours, and left overnight for 16 hours to dry in the oven at about 80° C., under indirect nitrogen flow. The resulting residue was very homogeneous.

About 2,913 mg of residue was obtained, which was ground into a fine powder. About 2,944 mg of the ground material was obtained; the increase in weight was likely due to absorption of water from the air. The ground powder was calcined under Ar flow at 850° C. for 20 minutes and 1 hour at about 500° C. After the calcining step, there was about 19.3% weight loss, and 2375.8 mg of the final product was obtained.

Preparation of Catalyst B (“Fe:Co:Mo”)

Catalyst B was a tri-component catalyst comprising Fe:Co:Mo in about a 1:0.23:⅙ molar ratio. To prepare the catalyst, 402 mg of Degussa Al₂O₃, 85.6 mg Fe₂(SO₄)₃·5H₂O, 10.5 mg of (NH₄)Mo₇O₂₄·4H₂O, and 12.6 mg of CoSO₄·H₂O are stirred together in 50 mL of deionized water and sonicated at 60° C. for 3.5 hours without stirring. The sonicated mixture was left for 17.5 h in an oven at 80° C. under a stream of nitrogen. About 495 mg of Fe/Co/Mo catalyst, having very homogeneous color, was obtained. After grinding the catalyst, about 500 mg of ground catalyst was obtained. The catalyst was calcined at 850° C. for 20 minutes. The weight loss was about 16.8%, and about 416 mg of catalyst B is obtained.

Preparation of Catalyst C (“Iron-Only Catalyst”)

Catalyst C was an Fe-only catalyst, prepared in a similar procedure to that described above, except using Al₂O₃ and Fe sulfate only. Catalyst C was prepared by suspending 800 mg of Al₂O₃ at 80° C. for about 1 hour in 100 mL of de-ionized water. Then about 171 mg of Fe₂(SO₄)₃·5H₂O was added, and the solution was stirred and sonicated at 50-60° C. for about 60 minutes. The solvent was removed, and the precipitate was calcined at about 850° C. for about 20 minutes. After calcining, the weight loss was about 16.1%, and about 815.64 mg of catalyst was obtained.

### Growth of SWNT Material

### Comparative Example 1

Comparative example 1 represents the typical CVD conditions of the prior art processes. The experimental procedure reported in J. Kong, A. M. Cassell, and H. Dai, Chemical Physics Letters, 292, 567-574 (1998) was followed. The CVD experiment was carried out by placing about 10 mg of the catalyst in a quartz tube mounted in a tube furnace. An argon flow was passed through the quartz tube as the furnace was heated to reach 1000° C. The argon flow was replaced by methane (99% purity) at a flow rate of 6150 cm³/min under 1.25 atm. head pressure. The methane flow lasted for about 10 minutes and was replaced by argon and the furnace was cooled to room temperature.

A few SWNT were produced in the product, but the yield was quite low, as evidenced by the Raman spectra, which was an order of magnitude weaker, as compared to the best CVD-grown SWNT samples.

### Standard Procedure for Examples 1-25

In examples 1-25, the following typical procedure was used for growing SWNT material. About 100 mg of catalyst was placed in a quartz boat, evenly spread at the bottom in a thin layer and placed in the CVD chamber. Next, the argon and methane gas lines were purged. Then, the Ar flow was established at a pressure of about 600 Torr (regulated by a valve) and the temperature in the CVD chamber was raised to the desired T_{g} (as shown in the Tables) under an Ar flow only. When the temperature reached the desired T_{g}, the methane flow was started. The flow rates are shown in the Tables. Typically, the SWNT growth continued for 1 hour. Then, the methane flow was completely shut down, and the temperature was brought down, under an argon flow, at a rate of about 20° C./min to a final temperature of about 25° C.

The material was then characterized by mass uptake (by comparing the mass of the catalyst before and after the CVD) and by resonant Raman (excitation wavelength 488 nm) scattering spectra.

### Examples 1-19

Examples 1-19 were carried out using catalyst A. CVD growth of SWNT material was carried out using the standard procedure described above. All experiments were carried out using Degussa™ Al₂O₃ support, and the growth time for all experiments was about one hour. The results are summarized in Table 1, below.

TABLE 1
SWNT growth Using Catalyst A (“Fe: Mo”); Total Pressure 600 Torr

| | | | WEIGHT | Ar FLOW | METHANE |
|---|---|---|---|---|---|
| | CATALYST | T_{g} | GAIN | RATE | FLOW |
| SAMPLE | (mg) | (° C.) | (%) | (sccm) | RATE (sccm) |
| 1 | 56 mg | 650 | ˜0 | 400 | 40 |
| 2 | 100 mg | 670 | 3.4 | 400 | 40 |
| 3 | 55 mg | 700 | 27 | 400 | 40 |
| 4 | 100 mg | 680 | 24.9 | 400 | 40 |
| 5 | 100 mg | 800 | 28.4 | 400 | 40 |
| 6 | 100 mg | 900 | 21.6 | 400 | 40 |
| 7 | 100 mg | 1,000 | 57.2 | 400 | 40 |
| 8 | 100 mg | 660 | 2.5 | 280 | 160 |
| 9 | 100 mg | 670 | 6.8 | 280 | 160 |
| 10 | 100 mg | 680 | 13.4 | 280 | 160 |
| 11 | 100 mg | 800 | 32.0 | 280 | 160 |
| 12 | 100 mg | 900 | 45.8 | 280 | 160 |
| 13 | 100 mg | 1,000 | 73.2 | 280 | 160 |
| 14 | 100 mg | 700 | 6.8 overall | 430 | 10 |
| | | | 16.0 only | | |
| | | | black part | | |
| 15 | 100 mg | 800 | 21.8 | 430 | 10 |
| 16 | 100 mg | 1,000 | 15.8 | 430 | 10 |
| 17 | 100 mg | 900 | 9.9 | 430 | 10 |
| 18 | 100 mg | 670 | 0 | 430 | 10 |
| 19 | 100 mg | 680 | 0 | 430 | 10 |

Table 1 shows the influence of temperature and flow rate on the growth of SWNTs. As shown in FIG. 6 and FIG. 7, it is apparent from the Raman data that although the weight gain increases with increasing temperature, the production of SWNT is optimized within a narrow growth temperature range, as evidenced by the Raman intensity.

With respect to Example 14, there was a slight variation in temperature in the sample (perhaps by only 1-2 degrees) due to the inevitable small temperature gradient along the furnace. The sample was spatially oriented such that one part of the sample was exposed to slightly lower temperature and the other part of the sample was exposed to a slightly higher temperature. Since 700° C. is on the low-temperature boundary of a very sharp growth window, the lower-temperature part of the sample was outside of the growth temperature range and therefore did not contain any SWNT material. The higher-temperature part of the sample was just inside the growth temperature range and contained high percentage of SWNT material. Although the overall weight gain was only 6.8%, the weight gain in the region inside the growth temperature window(i.e. the black part) was 16.0%.

For instance, in Examples 1-7, the optimal growth temperature range is 680-800° C. In Examples 8-13, the optimal growth temperature range is 710-750° C. In Examples 14-19, the optimal growth temperature range is 700-800° C.

In comparing the effect of the flow rate, it is observed that slower flow rates sharpen the low end of the T_{g} window. This illustrates how the T_{g} window can change, depending on methane flow rates.

### Examples 20-21

Examples 20-21 were carried out using catalyst B. CVD growth of SWNT material was carried out using the standard procedure described above. All experiments were carried out using Degussa™ Al₂O₃ support, and the growth time for all experiments was about one hour. The results are summarized in Table 2, below.

TABLE 2
SWNT growth Using Catalyst B (“Fe: Co: Mo”);
Total Pressure 600 Torr

| | | | | Ar FLOW | METHANE |
|---|---|---|---|---|---|
| | CATALYST | T_{g} | WEIGHT | RATE | FLOW |
| SAMPLE | (mg) | (° C.) | GAIN (%) | (sccm) | RATE (sccm) |
| 20 | 100 mg | 680 | 23.2 | 400 | 40 |
| 21 | 100 mg | 690 | 25.7 | 280 | 160 |

In studying how the addition of cobalt to the Fe:Mo catalyst affected the lower boundary temperature, the results seem to indicate that the lower boundary is shifted to higher temperatures by about 10° C. due to the addition of cobalt to the catalyst. Also, the boundary was about 5° C. higher in the case where the methane flow rate was 160 ccm as compared to 40 ccm.

### Examples 22-25

Examples 22-25 were carried out using catalyst C. CVD growth of SWNT material was carried out using the standard procedure described above. All experiments were carried out using Degussa™ Al₂O₃ support, and the growth time for all experiments was about one hour. The results are summarized in Table 3, below.

TABLE 3
SWNT growth Using Catalyst C (“Fe-Only”); Total Pressure 600 Torr

| | | | | Ar FLOW | METHANE |
|---|---|---|---|---|---|
| | CATALYST | T_{g} | WEIGHT | RATE | FLOW |
| SAMPLE | (mg) | (° C.) | GAIN (%) | (sccm) | RATE (sccm) |
| 22 | 100 mg | 780 | −1.2 | 400 | 40 |
| 23 | 100 mg | 800 | 10.7 | 400 | 40 |
| 24 | 100 mg | 850 | 7.5 | 400 | 40 |
| 25 | 100 mg | 750 | 7.5 | 400 | 40 |

It should be understood that the foregoing discussion and examples merely present a detailed description of certain preferred embodiments. It will be apparent to those of ordinary skill in the art that various modifications and equivalents can be made without departing from the spirit and scope of the invention. All the patents, journal articles and other documents discussed or cited above are herein incorporated by reference.

The claimed invention is:

1. A chemical vapor deposition process for the preparation of a single-wall carbon nanotube, comprising:
providing methane gas and a supported iron-containing catalyst to a chemical vapor deposition chamber, and
decomposing the methane in the presence of the supported iron-containing catalyst, under a sufficient gas pressure and for a time sufficient, to grow single-wall carbon nanotubes at a temperature from about 670° C. to about 800° C.

2. A process of claim 1, wherein said temperature is from about 670° C. to about 750° C.

3. A process of claim 1, wherein said temperature is from about 670° C. to about 700° C.

4. A process of claim 1, wherein said supported iron-containing catalyst is selected from the group consisting of: Al₂O₃/Fe/Mo/Co, Al₂O₃/Fe/Mo, Al₂O₃/Fe/Co, Al₂O₃/Fe, and mixtures thereof.

5. A process of claim 4, wherein the supported iron-containing catalyst is Al₂O₃/Fe/Mo catalyst, and wherein the catalyst has a ratio of Al₂O₃:Fe:Mo of about (10-20):1:⅓.

6. A process of claim 1, wherein said methane gas is methane or a mixture of methane and a carrier gas.

7. A process of claim 6, wherein said carrier gas is selected from the group consisting of: argon, nitrogen, helium, and mixtures thereof.

8. A process of claim 7, wherein said methane gas and said carrier gas are used in a ratio of about 1:1 by volume to about 1:10 by volume.

9. A chemical vapor deposition process for the preparation of single-wall carbon nanotubes, comprising:
providing methane gas and an Al₂O₃/Fe/Mo catalyst to a chemical vapor deposition chamber, and
decomposing the methane gas in the presence of the Al₂O₃/Fe/Mo catalyst, under a sufficient gas pressure and for a time sufficient, to grow single-wall carbon nanotubes at a temperature from about 670° C. to about 800° C.,
wherein said single-wall carbon nanotubes have a diameter distribution ranging from about 0.7 nm to about 2.1 nm.

10. A process of claim 9, wherein the Al₂O₃/Fe/Mo catalyst has a ratio of Al₂O₃:Fe:Mo of about (10-20):1:⅓.

11. A process of claim 9, wherein said temperature is from about 670° C. to about 750° C.

12. A process of claim 9, wherein said temperature is from about 670° C. to about 700° C.

13. A chemical vapor deposition process for the preparation of single-wall carbon nanotubes, comprising:
providing methane gas and an Al₂O₃/Fe/Co/Mo catalyst to a chemical vapor deposition chamber, and
decomposing the methane gas in the presence of the Al₂O₃/Fe/Co/Mo catalyst, under a sufficient gas pressure and for a time sufficient, to grow single-wall carbon nanotubes at a temperature from about 680° C. to about 800° C.
wherein said single-wall carbon nanotubes have a diameter distribution ranging from about 0.7 nm to about 2.1 nm.

14. A process of claim 13, wherein the Al₂O₃/Fe/Co/Mo catalyst has a ratio of Al₂O₃:Fe:Co:Mo of about (10-20):1:0.23:⅙.

15. A process of claim 13, wherein the Al₂O₃/Fe/Co/Mo catalyst has a ratio of Al₂O₃:Fe:Co:Mo of about (10-20):1:0.23:1/18.

16. A process of claim 13, wherein the Al₂O₃/Fe/Co/Mo catalyst has a ratio of Al₂O₃:Fe:Co:Mo of about (10-20):1:0.23:1/36.

17. A process of claim 13, wherein said temperature is from about 680° C. to about 750° C.

18. A process of claim 13, wherein said temperature is from about 680° C. to about 700° C.
